(19) United States
(12) Patent Application Publication
(10) Pub. No.: US 2009/0078203 A1
(43) Pub. Date: Mar. 26, 2009

(54) HOT SOURCE

(75) Inventors: Pekka Soininen, Helsinki (FI); Sami Sneck, Vantaa (FI)

Correspondence Address: OLIFF & BERRIDGE, PLC, P.O. BOX 320850, ALEXANDRIA, VA, 22320-4850, US

(73) Assignee: BENEQ OY, Vantaa (FI)

(21) Appl. No.: 12/297,342

(22) PCT Filed: Apr. 26, 2007
(86) PCT No.: PCT/FI2007/050232

§ 371 Date: Oct. 16, 2008

(30) Foreign Application Priority Data
Apr. 28, 2006 (FI) 20065275

(51) Int. Cl. C23C 16/00

(52) U.S. Cl. 118/726

(57) ABSTRACT

A hot source for vapour deposition apparatuses for supplying source substance into a reactor, the source comprising a source container having a source space for the source substance. The source further comprises a lid comprising first heating means for heating the lid, the lid being detachably installable in the source container in such a way that the heat generated by the first heating means is transmitted by conduction to the source container and further to the source space to heat the source substance.

### BACKGROUND OF THE INVENTION

The invention relates to a hot source used in ALD (Atomic Layer Deposition) and CVD processes (Chemical Vapour Deposition) for feeding source substance into a reactor. In particular, the invention relates, in accordance with claim 1, to a hot source for vapour deposition apparatuses for feeding source substance into a reactor, the source comprising a source container having a source space for the source substance.

When producing structures with vapour deposition methods, such as ALD and other CVD methods, the source substances must be turned into gaseous form before feeding them into the reactor space of a reactor, because in these processes the reaction takes place in the vapour phase in close interaction with the surface of the substrate. For many processes, there are no suitable source substances that would be gases in NTP conditions, so such processes must utilize liquids and solids. Since liquids and solids have low vapour pressures compared with the corresponding pressures of gaseous substances, they must often be heated to achieve a sufficient vapour pressure. Such heating is typically carried out at a pressure of approximately 10 to 50% relative to the system pressure of the reactor, when the source is used by means of what is called the overflow principle. If required, the temperature can be raised so high that the pressure of the source exceeds the system pressure of the reactor, whereby no overflow of gas is required but the source may be used at its own vapour pressure, so to say. To prevent condensation of vaporized source substances, these source substances must be conveyed into a reactor in such a way that all apparatus surfaces coming into contact with the source substance have either the same temperature as or a higher temperature than the source space in which the source substance is vaporized.

In accordance with prior art, hot sources are integrated into the inside of the reactor chamber and provided with locks by utilizing what is called inert gas valving. The problem with this solution is that when the substrate is to be changed, the locks required by the inert gas valving as well as the source substance must be cooled before changing the substrate. This slows down the operation of the reactor, subjects the source substance to undesired temperature variations and increases the number of contaminations from a higher pressure and the room air. Further, when such a source is used, the system pressure of the reactor may never drop below the vapour pressure of the source, because in such a case source substance would be discharged into the reactor uncontrollably. Also, due to the above aspects, the source substance cannot be kept in the source for longer times.

Another prior art solution for mounting a hot source on a vapour deposition reactor is to utilize metal bottles provided with valves, the solid source substance being placed inside the bottles and the bottle with its valves being positioned in a vacuum or convection furnace located next to the reactor or connected to it. The tubes from the bottle were provided with a resistance wire, for example, to avoid said condensation phenomena. This solution provides an inert way to mount a solid source but the highest possible operating temperature, i.e. approximately 200 to 250° C., is determined by the valves, the service life of which is significantly shortened at high temperatures. If the valves are positioned outside the furnace, some additional conduits must be provided and, moreover, cold bridges are generated in the structure. Such cold bridges are generated for instance in valves having actuator connections. Also, furnaces used for the purpose take a large amount of space and are expensive. The use of furnace solutions is also cumbersome because the bottles are big and heavy, and mounting and dismounting them requires tools. Metal bottles provided with valves are also expensive.

### BRIEF DESCRIPTION OF THE INVENTION

An object of the invention is thus to provide a hot source in such a way that the above problems can be solved. The object of the invention is achieved with a hot source according to the characterizing part of claim 1, characterized in that the source further comprises a lid comprising first heating means for heating the lid, the lid being detachably installable in the source container in such a way that the heat generated by the first heating means is transmitted by conduction to the source container and further to the source space to heat the source substance.

Preferred embodiments of the invention are disclosed in the dependent claims.

The invention is based on the idea that the source container of the source to be heated is formed in such a way that the source container which comprises a source space for source substance is provided with a lid detachable from the source container. The lid means, in this context, any structural part that is detachably attachable to the source container. Preferably, the lid is placed on the source container and closes thus the source space. The lid is further provided with first heating means that heat the lid in such a way that the heat can be transmitted by conduction from the lid to the source container detachably attached to the lid to heat the source space and the source substance in it. The lid is further provided with pipe systems and a feed channel that extends from the lid to the reactor to convey the source substance from the source space via the pipe systems and the feed channel of the lid into the reactor. The feed channel is provided with second heating means preferably positioned inside the feed channel for the source substance. In this way, a structure is provided in which it is possible, in all conditions, to maintain a rising temperature gradient between the source space and the reactor. In other words, an object of the invention is to provide a structure in which a heatable lid detachably attachable to the source space is formed for the source space, the lid comprising a heatable feed channel for feeding source substance into the reactor. The feed channel is thus in fluid communication with the source space of the source container via the pipe systems of the lid in such a way that by means of the heating means of the lid and the heating means of the feed channel a rising temperature gradient is achieved between the source container and the reactor. The lid needed by the source for actuators is provided with surface-mounting valves.

An advantage of the method and arrangement of the invention is that the source container and/or the source substance can be changed without cooling or opening the reactor. Further, no expensive furnaces are needed to heat the source substance, and mounting the source on the reactor is facilitated. Furthermore, the structure minimizes generation of cold points because the source of the invention allows a rising temperature gradient to be achieved in a simple manner between the source space and the reactor, which prevents condensation of the source substance. Still further, the modular structure of the source enables modification of the source according to the requirements of each specific use, whereby a required number of sources according to the invention can be connected to the reactor by installing sources in parallel or in series, for example. Further, by means of surface-mounting components provided for the heated lid, the temperature of the pipe systems and valves connected to the source can be kept above the condensation point in a simple and reliable manner.

### BRIEF DESCRIPTION OF THE FIGURES

The invention will now be described in greater detail in connection with preferred embodiments, referring to the attached drawings, of which:

FIG. 1 shows a cross-section of a hot source according to an embodiment of the present invention; and

FIG. 2 shows a top view of the hot source of FIG. 1.

### DETAILED DESCRIPTION OF THE INVENTION

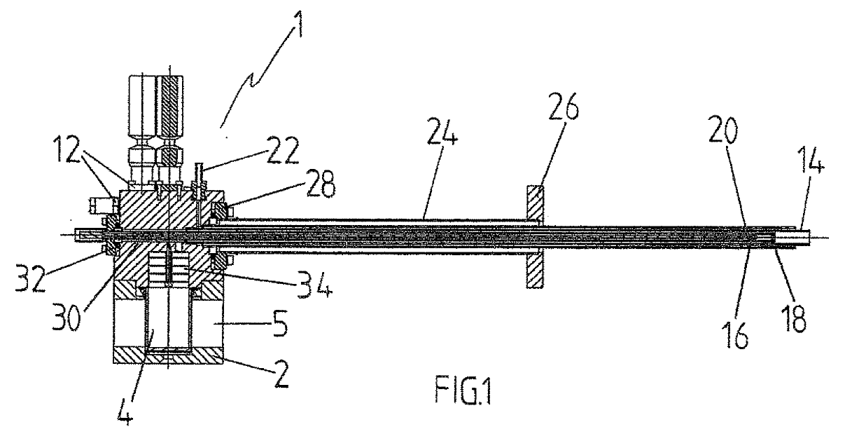

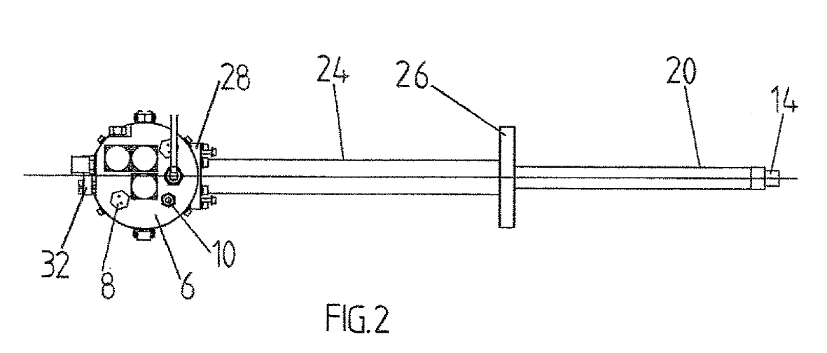

With reference to FIG. 1, it shows a cross-sectional view of an embodiment of a hot source 1 according to the present invention. The source 1 comprises a source container 2, in which a source space 4 of source substance is provided. The source container 2 is manufactured of material that conducts heat well, such as aluminium. Thus, the source container 2 is preferably of massive material, in which the source space 4 has been made by machining, or the source space 2 may have been manufactured by casting. In the embodiment according to FIG. 1 the source space 4 is a cylindrical space, but it may also be a space of another shape. The source space 4 is further provided with a cup or the like container made of glass or other inert material, in the inside of which the source substance can be placed. Preferably, one wall of the source space 4 is open in accordance with FIG. 1. In FIG. 1, this open wall is the upper wall of the source space 4. It is also possible to provide this open space with an openable lock or a valve-like structure, by means of which the source space 4 can be closed or separated from the surroundings. In this way, the source space can be kept closed when the source space has been detached from the source as well as during the installation of the source container 2, and it can be opened when the source space has been installed in place or when source substance is to be used in the process. The source container may further be provided with a window or the like structure that allows the source substance to be observed when the source container has been installed in the source. Thus, the behaviour and sufficiency of the source substance can be optically monitored. Upon the source container a lid 6 has been installed which becomes placed upon the source space 4. The lid 6 and the source container 2 are preferably attachable to each with quick-release locking, such as a bolt structure, that allows the source container 2 to be detached from the lid 6 easily and quickly. The locking means of the source space can be connected to the installation and detachment of the source container 2 in such a way that the locking means open the source space 4 when the source container is installed in place, and reclose the source space when the source container 2 is detached from the lid 6. The locking means may be a valve-like structure or a hatch-like structure or the like, the operation of which may be automated for attaching and detaching the source container 2 from the lid 6, or the operation of which may be controlled separately. The lid 6 is provided with first heating means 8 (FIG. 2) for heating the lid 6. The first heating means 8 may be, for example, changeable heating cartridges, heat cartridges or heating resistors, of which there may be one or several in the lid. Like the source container 2, the lid 6 is preferably manufactured of heat-conductive material, such as stainless steel, aluminium or alloys of these, or other corresponding material. The lid 6 and the source container 2 as well as the connection between them has been provided in such a way that the heat generated with the first heating means 8 can be transmitted by conduction from the lid 6 to the source container 8. Thus, the source container 2 and the lid 6 become placed against each other, enabling conduction of heat. This means that in the solution according to the invention there is no need to heat the source space 4 separately, but the source space 4 is heated by the heat conducted from the lid 6.

The lid 6 is provided with surface-mounting means and/or surface-mounting valves 12 for connecting actuators and inlet conduits and other components to be installed in the source. The surface-mounting means 12 are designed to withstand high temperatures, and their cold bridges have been minimized. Utilizing surface-mounting technology allows the surface-mounting valves and the other surface-mounting means to be kept at nearly the same temperature as the rest of the parts of the lid 6, and always at a higher temperature than the source volume 4, because the lid 6 is provided with the first heating means 8. The lid 6 is further provided with feed means for feeding source substance from the source space 4 of the source container 2 into the reactor 4 (not shown). The lid 6 is provided with pipe systems (not shown), which are connected from the surface mountings 12 as well as the conduits and actuators brought to them to the source space 4 of the source container 2 when the source container 2 has been installed in the lid 6. Further, the lid 6 comprises pipe systems that are connected from the source space 4 to the feeding means for supplying source substance from the source space into the feeding means and from there further into a reactor. The lid 6 is preferably massive, whereby the above-mentioned pipe systems have been provided for it by machining, such as boring, or in another corresponding manner. Pipe systems provided by machining do not need to be heated separately because their heating is implementable by means of the first heating means 8 provided for the lid 6. In this context, a reactor refers to any reactor of a vapour deposition apparatus, such as the reactor of a CVD, ALD or MCVD apparatus or the like. The interior of the reactor comprises a reactor space formed by the reactor's outer walls, or alternatively the interior of the reactor may comprise a separate reaction chamber forming a reactor space, to which the source substances are conveyed.

The lid 6 is further provided with a feed channel 14, along which the source substance flows into the reactor. Around the feed channel 14, a coaxial additional channel 20 is installed in accordance with FIG. 1 in such a way that a gap remains between the feed channel 14 and the additional channel 20, along which gap a nitrogen gas flow of an inert gas valving can be supplied, whereby it flows between the feed channel 14 and said additional channel 20. The feed channel 14 and the additional channel 20 are preferably made of glass and have a circular cross-section. If required, also two or more such additional channels may be added around the feed channel 14. The feed channel 14 is, by means of the pipe systems of the lid 6, in fluid communication with the source space 4 of the source container, whereby the vaporized source substance can flow from the source space via the pipe systems of the lid 6 into the feed channel 14 and further into the reactor. Nitrogen gas or other corresponding gas may further be brought to the space between the feed channel 14 and the additional channel 20 by means of a gas conduit 22 provided for the lid 6 with surface mounting via the pipe system provided for the lid 6. The feed channel 14 and the additional channel 20 are, along part of their length, further surrounded and supported by a casing 24 extending between the lid 6 and the reactor. The casing 24 as well as the feed channel 14 and the additional channel 20 are installed in a recess in the lid 6 and fastened to the lid 6 with fastening means 28, such as a flange structure. The end of the casing 24 on the side of the reactor is, in turn, provided with a flange 26 for attachment to the reactor. The feed channel 14 and the additional channel 20 further extend outwards from the flange 24 over the flange 26 in order to extend to the reactor chamber of the reactor when having been installed in place.

To keep the vaporized source substance at a sufficiently high temperature in the feed channel 14 to prevent condensation, second heating means 16 have been installed inside the feed channel and enclosed inside a protecting pipe 18. These second heating means 16 are preferably a resistor arranged to be adjustable with adjusting means in such a way that the temperature of the resistor can be adjusted to the desired level in each particular case. The second heating means 16 may also be heating means other than a resistor. These second heating means 16 heat the feed channel 14 and particularly its inner wall, and thus also the source substance flowing in the feed channel 14, to a sufficiently high temperature or maintain the temperature of the source substance to prevent condensation. The second heating means 16 extend in the feed channel preferably so far that the thermal effect of the reactor is able to maintain the required temperature of the source substance in the feed channel to prevent condensation. The second heating means 16 being installed in the feed channel, the source substance can flow in the space between the protecting pipe 18 and the feed channel 14. The feed channel 14, the additional channel 20 and the protecting pipe 18 are preferably manufactured of inert material, such as glass. In accordance with FIG. 1, the lid 6 is provided with a feedthrough extending from the installation point of the feed channel 14 on one side of the lid 6 through the lid to its other side in such a way that the second heating means 16 are installable inside the feed channel 14 by taking them through the feedthrough 30 from one side of the lid to the feed channel 14. The second heating means 16 are further attachable to the lid 6 by means of a flange structure 32 or another corresponding arrangement. Since the feed channel 14 extends from the lid 6 heated with the first heating means 8 to the reactor, a rising temperature gradient is achieved between the source space 4 and the feed channel, and further, since the feed channel is heated with the second heating means 16, a rising temperature gradient is achieved between the feed channel 14 and the reactor or between the lid 6 and the reactor. Thus, it is possible to achieve a rising temperature gradient along the whole way from the source space 4 to the reactor, or at least the temperature does not drop below the temperature of the source space (4) in any part on the way to the reactor.

The feedthrough 30 and the openings on opposite sides of the lid 6 for installing the feed channel 14 and for installing the heating means to be installed inside the feed channel, respectively, allow two or more sources according to the invention to be installed successively in series. Thus, for instance after the source shown in the embodiment of FIG. 1, a second source is placed in such a way that instead of the second heating means, the feed channel of this second source extends to the reactor inside the feed channel of the source shown. The second heating means are thus placed as in FIG. 1, but in such a way that they extend continuously through the feed channels of both sources when installed through the feedthrough of the second source inside the feed channels. It is also possible to install two or more hot sources according to the invention in parallel in such a way that the sources utilize the same feed channel extending to the reactor. When several sources are connected in parallel or in series, it is, however, necessary in all cases to use such temperatures in the sources and feed channels that the temperature gradient generated is always rising on the way towards the reactor. In other words, this is implemented for instance when several sources are installed in series in such a way that the temperature of the source closer to the reactor is always higher than that of the source farther off from the reactor. Thus, different source substances with different vaporizing temperatures can be vaporized in different sources. Thus, the source substances having a higher vaporizing temperature are positioned in the sources closest to the reactor. In this way, a temperature gradient rising towards the reactor is ensured in such a way that the vaporized source substances will not condensate on the surfaces of the apparatus on the way to the reactor.

In accordance with FIG. 1, the lid 6 can be further provided with a filter 34, which becomes placed above the source space 4 when the source container 2 has been installed in place. The purpose of the filter 34 is to prevent particles of dusty source substances from getting into the feed channel and further into the reactor. For example, when using solid source substances that easily make dust, a filter 34 is installable in the upper part of the source container 4 to prevent the possibility of dust getting into the feed pipe system of the reactor and through that onto the surface of the substrates. Such a filter may be for instance a wire mesh, a sinter or, as in FIG. 1, a “labyrinth” assembled of several plates. The operation of the latter is based on the idea that in order to travel from the surface of the source substance into the feed pipe system, the particles must be able to permeate a winding structure having large surface areas. Each plate in the structure has a hole or a corresponding opening, through which the particles must first get. Subsequently, the speed of the particles slows down when the gas arrives in a greater volume. Thus, the particles tend to adhere to the walls of this volume. When proceeding to the next space, it is again necessary to go through a throttling opening, etc. In practice the gas flow going through the labyrinth is, for the most part, diffusion flow, the capability of which to transfer particles is non-existent. During the pulsing, mainly the volume above the “labyrinth”, and if required, also the uppermost volumes of the labyrinth, are emptied The openings made are sufficiently large in order not to cause any significant flow resistance, which allows the upper volume to be filled more rapidly between the pulsing times, compared with many sinter and mesh solutions. Correspondingly, during a pulse, the particles possibly carried by a flow generated by the suction and greater than the diffusion flow are filtered into the structure. Further, when using what is called the Overblow state, the powder-spreading effect of the carrier gas blown into the source is prevented by breaking the flow to the uppermost plate of the labyrinth.

The structure according to the invention and particularly the lid 6 can be further provided with a relief valve, a crystal-water discharge pipe system, an intermediate volume of the stored source substance vapour, which is to be emptied in the pulsing, and the like known features.

FIG. 2 shows a top view of the hot source of FIG. 1. In accordance with the figure, the lid 6 is provided with first heating means 8, which are embedded within the massive lid. Further, the lid 6 comprises temperature-measuring means 10 for measuring the temperature of the lid and/or the source container installed in it. On the basis of the temperature measurements obtained, the first heating means can be adjusted to achieve a suitable temperature in the source container and source space. The temperature measuring means 10 can also be used merely for observing the temperature. FIG. 2 also shows the surface-mounting means and surface-mounting valves 12 for installing actuators and conduits in the lid 6. These surface-mounting means and surface-mounting valves 12 are preferably integrated into the lid 6. The feed channel 14 for the source substance and the surrounding additional channel 20, which are positioned inside the casing 24, extend from the lid 6 to the right in the figure. The former are attached to the lid 6 with a flange structure 28. The casing 24 further comprises a flange 26 for attachment to the reactor. On the side opposite the feed channel, there is a second flange structure 32, by means of which second heating means are attachable to the lid 6 and from which a feedthrough extends through the lid 6 to the feed channel.

Although in FIGS. 1 and 2 and in the solutions explained, the lid 6 is installed upon the source container, the source structure can also be formed such that the lid 6 is installable on one side of or even underneath the source container, whereby the source space is at least partly open in the direction of the lid 6. The source space may be open to one side in the horizontal direction, for example, whereby the lid is installed on one side of the source container upon this open side. What is substantial in the invention is that there is a lid installable in a source container, which lid is at a higher temperature than the source container and through which lid the source substance flows into a feed channel that is, in turn, at a higher temperature than the lid. Thus, a temperature gradient rising towards the reactor is achieved, which prevents the condensation of the source substance.

It will be obvious to a person skilled in the art that with the advance of technology the basic idea of the invention can be implemented in a plurality of ways. The invention and its embodiments are thus not restricted to the above examples but may vary within the scope of the claims.

1. A heatable source positioned outside a reactor for vapour deposition apparatuses for supplying source substance into a reactor, the source comprising a source container having a source space for the source substance, which source container is detachably attachable to a lid having first heating means for heating the lid in such a way that the heat is transmitted by conduction to the source container and further to the source space to heat the source substance, wherein the lid further comprises a heatable feed channel in fluid communication with the source space for supplying source substance from the source space into the reactor in such a way that a rising temperature gradient is achievable between the source container and the reactor.

2. A hot source according to claim 1, wherein the first heating means comprise one or more heat cartridges changeably installable in the lid.

3. A hot source according to claim 1, wherein the first heating means comprise one or more heating resistors installed in the lid.

4. A hot source according to claim 1, wherein the lid further comprises a thermometer for measuring and adjusting the temperature of the lid to adjust the temperature of the source container and the source space to the desired level.

5. A hot source according to claim 1, wherein the lid further comprises one or more surface-mounting means and/or surface-mounting valves for connecting actuators or inlet conduits to the source.

6. A hot source according to claim 1, wherein the lid comprises pipe systems, through which the source substance is feedable from the source space into a feed channel installed in the lid and further into the reactor.

7. A hot source according to claim 6, wherein at least part of the pipe system of the lid is provided for the lid by boring or by machining in another way.

8. A hot source according to claim 6, wherein the feed channel comprises second heating means for heating the feed channel and the substance flowing in it.

9. A hot source according to claim 6, wherein the feed channel comprises a first tubular channel part for supplying source substance into the reactor, and one or more tubular additional channel parts installed around the first channel part for supplying carrier gas or other process gas.

10. A hot source according to claim 8, wherein the second heating means are formed elongated in such a way that they are installable inside the feed channel.

11. A hot source according to claim 10, wherein the second heating means are provided with a protection pipe placed upon them.

12. A hot source according to claim 1, wherein the second heating means are provided to be adjustable in such a way that by means of the first and the second heating means, a rising temperature gradient is achievable between the source container and the reactor through the lid and the feed channel.

13. A hot source according to claim 1, wherein the source is provided with a quick-release means for attaching and detaching the source container from the lid.

14. A hot source according to claim 1, wherein it comprises connecting means for connecting two or more corresponding hot sources in series or in parallel.

15. A hot source according to claim 1, wherein the source container is provided with a window or the like transparent portion for optic observation of the amount and behaviour of the source substance.

16. A hot source according to claim 1, wherein the source container is manufactured of aluminium or other material that conducts heat well.

17. A hot source according to claim 1, wherein the lid is manufactured of aluminium or an alloy of stainless steel and aluminium.

18. A hot source according to claim 1, wherein it further comprises a filter for preventing particles from getting from the source space into the feed channel and further into the reactor.

19. A hot source according to claim 18, wherein the filter comprises a labyrinthic structure through which the gas is arranged to flow.
